(19) United States
(12) Patent Application Publication
(10) Pub. No.: US 2009/0297957 A1
(43) Pub. Date: Dec. 3, 2009

(54) EXPOSURE MASK AND METHOD FOR MANUFACTURING SEMICONDUCTOR DEVICE USING THE SAME

(75) Inventor: Jae In Moon, Seoul (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/343,185

(22) Filed: Dec. 23, 2008

(30) Foreign Application Priority Data
May 27, 2008 (KR) 10-2008-0049166

(51) Int. Cl. G03F 7/20; G03F 1/00

(52) U.S. Cl. 430/5; 430/313

(57) ABSTRACT

Disclosed herein are an exposure mask and a method for manufacturing a semiconductor device using the same. The exposure mask comprises a first transparent pattern having a rectangular shape for forming an expected contact hole region, and a second transparent pattern formed at both long sides of the first transparent pattern, thereby maintaining a process margin and obtaining a contact hole with reduced exposure energy.

### CROSS-REFERENCE TO RELATED APPLICATION

Priority to Korean patent application number 10-2008-0049166, filed on May 27, 2008, the disclosure of which is incorporated by reference in its entirety, is claimed.

### BACKGROUND OF THE INVENTION

1. Field of the Invention

The present invention relates generally to an exposure mask and a method for manufacturing a semiconductor device using the same, and more specifically, to a technology of improving a margin of an exposing process in a microlithography process.

2. Description of Related Technology

A mask is typically used in an exposure process to form a circuit and design structure. However, usage of the mask causes problems due to size reduction.

When a high density pattern is formed, off-axis illumination has been widely used. Off-axis illumination is performed using a device selected from a dipole illuminator, a quadropole illuminator, a crosspole illuminator, and a quasar.

FIG. 1 is a plane diagram illustrating a conventional exposure mask.

Referring to FIG. 1, the exposure mask includes a shading pattern 11 that defines a transparent region 13 over a quartz substrate.

The transparent region 13 is formed to have a bar shape with a minor axis “A” and a major axis “B”. The transparent regions 13 are arranged in a row along the minor axis direction (i.e., the direction with high density).

FIG. 2 is a scanning electron microscope (SEM) photograph illustrating a drain contact hole of a flash memory formed with the mask of FIG. 1.

A drain contact as shown in FIG. 2 is formed by a method including forming an underlying layer over a semiconductor substrate, forming a photoresist film over the underlying layer, and exposing and developing the photoresist film with the exposure mask of FIG. 1 to form a photoresist pattern.

When the exposure mask of FIG. 1 is used, the exposure energy (Eop) for development is too high. When the exposure energy is high, the corresponding exposure process time can take too long.

Although the long exposure process time can be reduced by enlarging the size of the minor axis (A) and the major axis (B), mask errors are then generated, critical dimension uniformity is degraded, and the margin of the exposing process is reduced.

### SUMMARY OF THE INVENTION

Various embodiments of the present invention are directed at providing an exposure mask and a method for manufacturing a semiconductor device using the same.

According to an embodiment, an exposure mask comprises: a first transparent pattern having a rectangular shape for exposing an expected contact hole region; and a second transparent pattern formed at both long sides of the first transparent pattern.

The second transparent pattern is preferably a subsidiary transparent pattern.

The second transparent pattern preferably has a bar shape and is oriented perpendicular to a long side of the first transparent pattern.

The second transparent pattern preferably has a critical dimension of about 10 nm to about 80 nm.

The second transparent pattern is preferably formed a distance from both end portions of the long side of the first transparent pattern.

The second transparent pattern is preferably formed at a center and at both end portions of the long side of the first transparent pattern.

The second transparent pattern is preferably connected with the long sides of the first transparent pattern.

The second transparent pattern is preferably formed between the top and bottom end portions of the first transparent pattern.

The exposure mask is preferably selected from a binary mask, a phase inversion mask, and a half-tone phase inversion mask.

According to an embodiment, a method for manufacturing a semiconductor device comprises: forming an underlying layer over a conductive layer; forming a photoresist film over the underlying layer; forming a photoresist pattern by exposing and developing the photoresist film by a lithography process with the exposure mask of claim 1; and etching the underlying layer with the photoresist pattern as a mask to form a contact hole that exposes the conductive layer.

Forming-a-photoresist-pattern is preferably performed using a dipole illuminator. Forming-a-photoresist-pattern can also be performed using an off-axis illumination apparatus selected from a quadropole illuminator, a crosspole illuminator, and a quasar.

### BRIEF DESCRIPTION OF THE DRAWINGS

FIG. 1 is a diagram illustrating a conventional exposure mask.

FIG. 2 is a SEM photograph illustrating a drain contact formed with the exposure mask of FIG. 1.

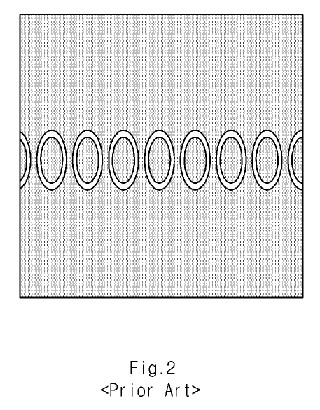

FIG. 3 is a plane diagram illustrating a unit transparent pattern of an exposure mask according to an embodiment the invention.

FIG. 4 is a plane diagram illustrating an exposure mask according to an embodiment of the present invention.

FIG. 5 is a plane diagram illustrating a photoresist pattern formed with the exposure mask of FIG. 4.

FIG. 6 is a plane diagram illustrating an aerial image formed in an exposing process with the exposure mask of FIG. 4.

FIG. 7 is a graph illustrating the comparative optical distribution of x-x of FIG. 1 relative to y-y of FIG. 4.

FIG. 8(a) is a diagram illustrating a simulation result of a contact hole formed with the exposure mask of FIG. 1. FIG. 8(b) is a diagram illustrating a simulation result of a contact hole formed according to an embodiment of the present invention.

While the disclosed method is susceptible of embodiments in various forms, specific embodiments are illustrated in the drawings (and will hereafter be described), with the understanding that the disclosure is intended to be illustrative, and is not intended to limit the invention to the specific embodiments described and illustrated herein.

### DETAILED DESCRIPTION

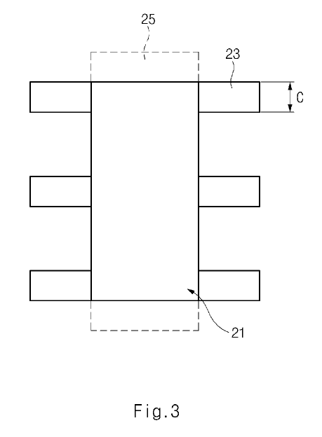

FIG. 3 is a diagram illustrating a unit transparent pattern in an exposure mask according to an embodiment of the invention. The unit transparent pattern is required to form a contact hole. In the exposure mask, the unit transparent patterns of FIG. 3 are continuously formed in a minor axis direction (horizontal direction) of a main transparent pattern 21.

The unit transparent pattern includes a main transparent pattern 21 having a rectangular shape that exposes an expected contact-hole region, and subsidiary transparent patterns 23 having a bar shape formed at both sides of a major axis direction (vertical direction) of the main transparent pattern 21. The subsidiary transparent pattern 23 preferably contacts the long side perpendicular to the major axis direction of the main transparent pattern 21.

Referring to FIG. 3, the subsidiary transparent patterns 23 are preferably formed at both end portions and at the center of both long sides of the main transparent pattern 21. The width (C) of the subsidiary transparent pattern 23 has a size so as not to be developed in the corresponding off-axis illumination exposure condition. The width (C) preferably ranges from about 10 nm to about 80 nm. Thus, the subsidiary transparent pattern region advantageously increases the energy projected into the main transparent pattern region, but is not developed. As a result, the mask according to the embodiment requires less exposure energy than the mask formed to include only a rectangular transparent region as shown in FIG. 3.

The main transparent pattern 21 is preferably formed to have a longer major axis direction with a protrusion tab element 25 extending beyond an outermost edge of the subsidiary transparent pattern 23.

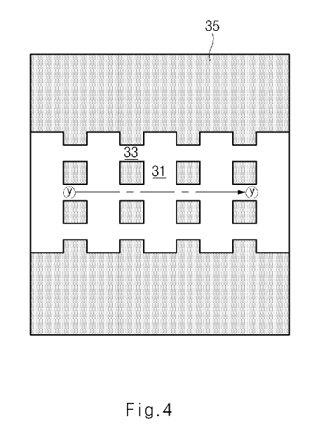

FIG. 4 is a plane diagram illustrating an exposure mask according to an embodiment of the invention. FIG. 4 shows that unit transparent patterns are continuously formed with high density.

The unit transparent pattern of the exposure mask includes a first transparent pattern 31, which is a transparent pattern for exposing an expected contact hole region, and a second transparent pattern 33, which is a subsidiary transparent pattern. The exposure mask includes unit transparent patterns that are continuously connected in a minor axis direction (horizontal direction) of the first transparent pattern 31.

The exposure mask may be used in a number of semiconductor manufacturing applications, e.g., when a drain contact of a flash memory device is formed. The exposure mask includes one selected from a binary mask, a phase inversion mask and a half-tone phase inversion mask.

The first transparent pattern 31 is a rectangular transparent pattern that exposes an expected contact-hole region. The second transparent pattern 33 is a subsidiary transparent pattern having a bar shape and is oriented perpendicular to both long sides of the first transparent pattern 31. The second transparent pattern 33 is formed between top and bottom edges of the first transparent patterns 31, for example, in the center and separated by a given distance from the center (preferably, at both end portions).

The second transparent pattern 33 is preferably formed having a bar shape to have a critical dimension ranging from about 10 nm to about 80 nm.

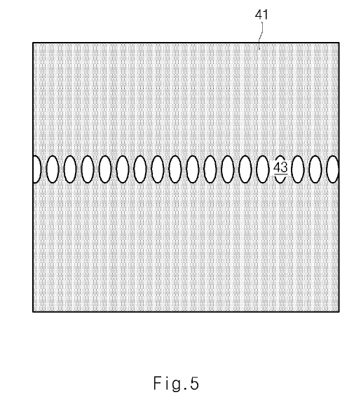

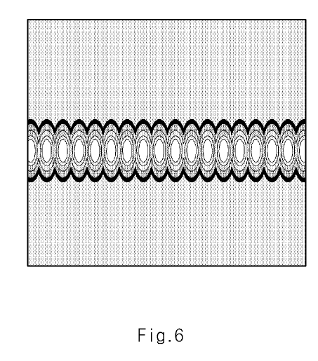

FIG. 5 is a plane diagram illustrating a photoresist pattern formed over a semiconductor substrate by an exposing and developing process with the exposure mask of FIG. 4. FIG. 6 is a plane diagram illustrating an aerial image formed in an exposing process with the exposure mask of FIG. 4.

Referring to FIG. 5, an underlying layer (not shown) is formed over a semiconductor substrate (or conductive layer), and a photoresist film 41 is coated over the underlying layer. The underlying layer preferably includes an insulating material, such as an oxide film.

The photoresist film 41 is exposed with the exposure mask of FIG. 4, and the exposed photoresist film is developed to form a photoresist film 41 having a patterned contact hole region 43. The exposing process is preferably performed by a lithography process using a dipole illuminator. Forming a photoresist pattern can also be performed using an off-axis illumination apparatus selected from a quadropole illuminator, a crosspole illuminator, and a quasar.

In the exposing process, the exposure energy is concentrated on the contact hole region 43, as shown in FIG. 6, that is, the first transparent pattern region. As a result, the second transparent pattern region is not developed.

The underlying layer (not shown) is etched until the semiconductor substrate is exposed with the photoresist film 41 as an etching mask, thereby obtaining an underlying pattern, that is, a contact hole 43. The photoresist film 41 then is removed.

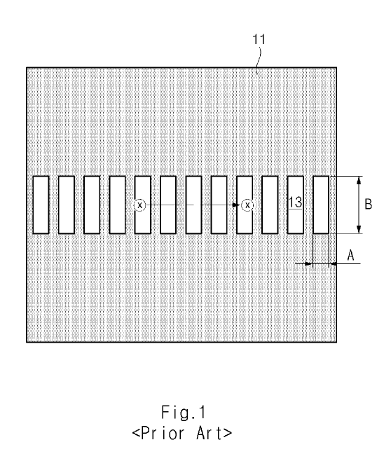

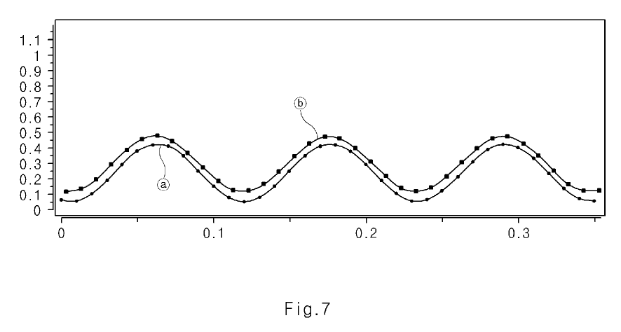

FIG. 7 is a graph illustrating an optical distribution of x-x of FIG. 1 and y-y of FIG. 4.

Referring to FIG. 7, \textcircled{a} is a graph illustrating optical distribution of \textcircled{x}-\textcircled{x} of FIG. 1, and \textcircled{b} is a graph illustrating optical distribution of \textcircled{y}-\textcircled{y} of FIG. 4. In the graph, the X axis represents a distance, and the Y axis represents the size of the exposure energy.

In comparison of \textcircled{b} of the present invention with \textcircled{a} of the conventional art, FIG. 7, shows that the light strength becomes larger by 30 to 50% while a curved shape is maintained. When the mask of FIG. 4 is used, the exposure energy is increased while being concentrated on the contact hole region like in the conventional art.

When the exposure mask of the present invention is used, the conventional contact hole pattern can be obtained even when the exposure energy is reduced by an energy strength difference shown in FIG. 7.

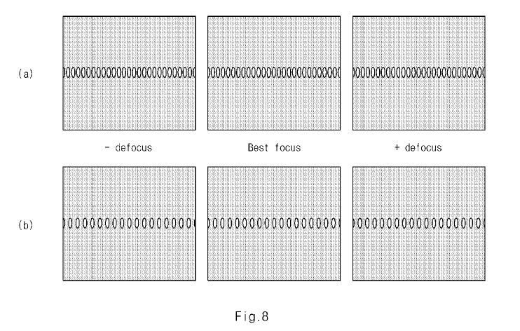

FIG. 8(a) is a diagram illustrating a simulation result on a contact hole formed with the exposure mask of FIG. 1. FIG. 8(b) is a diagram illustrating a simulation result on a contact hole formed with the exposure mask of FIG. 4 using the exposure energy reduced by an energy strength difference shown in FIG. 7.

The center shows when the depth of focus is the best focus, and the left and right sides show when the depth of focus is defocused.

Although the exposure energy reduced by an energy strength difference of FIG. 7 is used, an interval between the contact holes can be maintained. That is, the process margin can be maintained while the exposure energy is reduced.

Although the drain contact hole of a flash memory device is formed in the embodiment, the mask according to an embodiment of the invention can also be applied when dense storage electrode contacts are formed in the manufacturing of DRAM devices.

As described above, an exposure mask according to an embodiment includes a subsidiary transparent pattern having a bar shape perpendicular to both long sides of a rectangular transparent pattern, thereby facilitating an exposing process with reduced light strength and maintaining process margin. As a result, even in a defocus state, the present invention can provide a pattern having an excellent profile, thereby facilitating high-integration of semiconductor devices.

The above embodiments of the disclosure are illustrative and not limiting. Various alternatives and equivalents are possible. The invention is not limited by the type of deposition, etching, polishing, and patterning steps described herein. Nor is the invention limited to any specific type of semiconductor device. For example, the disclosure may be implemented in a dynamic random access memory (DRAM) device or a non-volatile memory device. While the present invention has been described with respect to the specific embodiments, it will be apparent to those skilled in the art that various changes and modifications may be made without departing from the spirit and scope of the invention as defined in the following claims.

What is claimed is:

1. An exposure mask comprising:
a first transparent pattern having a rectangular shape for exposing an expected contact hole region; and
a second transparent pattern formed at both long sides of the first transparent pattern.

2. The exposure mask according to claim 1, wherein the second transparent pattern is a subsidiary transparent pattern.

3. The exposure mask according to claim 1, wherein the second transparent pattern has a bar shape and is oriented perpendicular to a long side of the first transparent pattern.

4. The exposure mask according to claim 1, wherein the second transparent pattern has a critical dimension of about 10 nm to about 80 nm.

5. The exposure mask according to claim 1, wherein the second transparent pattern is formed a distance from both end portions of the long side of the first transparent pattern.

6. The exposure mask according to claim 1, wherein the second transparent pattern is formed at a center and at both end portions of the long side of the first transparent pattern.

7. The exposure mask according to claim 1, wherein the second transparent pattern is connected with the long sides of the first transparent pattern.

8. The exposure mask according to claim 1, wherein the exposure mask is selected from a binary mask, a phase inversion mask, and a half-tone phase inversion mask.

9. The exposure mask according to claim 1, wherein the second transparent pattern is formed between the top and bottom end portions of the first transparent pattern.

10. A method for manufacturing a semiconductor device, the method comprising:
forming an underlying layer over a conductive layer;
forming a photoresist film over the underlying layer;
forming a photoresist pattern by exposing and developing the photoresist film by a lithography process with the exposure mask of claim 1; and,
etching the underlying layer with the photoresist pattern as a mask to form a contact hole that exposes the conductive layer.

11. The method according to claim 10, wherein forming-a-photoresist-pattern is performed using a dipole illuminator.

12. The method according to claim 10, wherein forming-a-photoresist-pattern is performed using an off-axis illumination apparatus selected from a quadropole illuminator, a crosspole illuminator, and a quasar.
